(19) United States
(12) Patent Application Publication
(10) Pub. No.: US 2010/0070221 A1
(43) Pub. Date: Mar. 18, 2010

(54) System and Method for Sample Point Analysis with Threshold Setting

(75) Inventor: Richard A. Altimus, Massillon, OH (US)

Correspondence Address: PATENTFORGE, 1725 SE 72ND, PORTLAND, OR, 97215, US

(73) Assignee: Nexus Technology, Nashua, NH (US)

(21) Appl. No.: 12/433,965

(22) Filed: May 1, 2009

Related U.S. Application Data
(60) Provisional application No. 61/096,782, filed on Sep. 13, 2008.

(51) Int. Cl. G01R 13/02; G06F 19/00

(52) U.S. Cl. 702/66

(57) ABSTRACT

A signal analysis system that may include threshold setting for analyzing analog signals. The system may include a plurality of digitizers and adjustable power supplies for supplying threshold voltages for the digitizers. The system may digitize a set of analog signals, locate features and attributes in the digitized signals and determine a duty cycle for signals based on the signal features and attributes. The determined duty cycle may then be used to set threshold voltages on the power supplies.

### RELATED APPLICATIONS

This application claims priority to U.S. Provisional application Ser. No. 61/096,782 filed Sep. 13, 2008. and entitled “Method for Setting Threshold Values and Sample Point Analysis” which is hereby incorporated by reference in its entirety for all purposes.

### BACKGROUND

This disclosure relates generally to signal analysis methods and more particularly to systems and methods for analyzing electronic signals and setting parameters for digitizing a set of simultaneous signals.

Examples of systems and methods for analyzing electronic signals and setting parameters for digitizing signals are found in the following US patents and Publications: 20060190200; 20060245528; 20070006054; 20070262799; 20070297548; U.S. Pat. Nos. 6,075,478; 6,218,976; 6,351,231 6,882,944; 7,113,749; 7,227,349; 7,250,884 and 7,265,707. The disclosures of these references are hereby incorporated by reference in their entirety for all purposes.

### SUMMARY

Integrated circuits operate using binary logic and transmit analog signals over lines with bond wires, traces and leads to other integrated circuits. Integrated circuits function at high speeds with multiple simultaneous and complex signals.

Integrated circuit functions are typically characterized by a logic analyzer or analysis system which connects to the integrated circuit and simultaneously digitizes the signals on each signal line. The analyzer may then statically display the signals in a manner that allows the operator to see the functions and dependencies between the individual signals. Critical to the process of digitizing an analog voltage signal is setting a threshold voltage.

The analog signal typically alternates between a low voltage and a high voltage, for example 0 and 2 volts. Digitizing the analog signal includes comparing the signal voltage to a threshold and outputting a value of zero or one depending on whether the analog voltage is below or above the threshold voltage. In this example the threshold may be 1 volt.

In an ideal signal, the analog voltage goes from 0 to 2 volts instantaneously and resembles an ideal square wave. An ideal clock signal oscillating between a high and low voltage in a regular cycle when digitized by an analyzer will display digital pulses of identical width. The percentage of time this digitized signal is in a zero or a one state (the duty cycle) will be 50%.

In reality, signal line physical characteristics such as discontinuities, capacitance, inductance and other factors result in an analog signal that takes on characteristics of a sine wave. A finite amount of time is required for the analog signal to change from low to high. High and low signals may not reach the specification values of 0 and 2 volts, but may only reach 0.1 volts and 1.8 volts. A threshold of 1 volt in such a situation may produce a digitized representation where the width of the zero states does not equal the width of the one states. The duty cycle of the digitized signal in this case may not be equal to 50% and errors may occur. The analog signals may be digitized incorrectly and the static data displayed may be inaccurate.

The threshold is typically set so that the duty cycle is within a specified tolerance. Setting the thresholds manually by inspection is a labor-intensive and time-consuming process involving additional equipment such as an oscilloscope. This is especially true given the number of signals that can be involved. DDR3 memory may have 64 data signal lines and 8 ECC bit signal lines that may each require threshold setting.

Setting threshold values automatically on a plurality of simultaneous analog signal lines and establishing sample points in the digitized signal would reduce equipment requirements, simplify procedures and increase accuracy.

An automated digitizing or analyzing system may include a logic analyzer or other digitizing system for analyzing signals connected to an integrated circuit generating simultaneous signals on separate signal lines. A characteristic set of data generated by the integrated circuit from each signal line may be digitized and stored in the analyzer for each data line for analysis. The characteristic data generated by the integrated circuit and analyzed by the system may be any data compatible with the configuration of the threshold setting system.

DDR3 memory may generate data bursts of 4 or 8 successive bits of data for each signal line. This set of data may be collected by the analyzer, digitized and used as the basis for determining the duty cycle for the digital data. Data burst technology is well known to persons skilled in the art and may include in each read or write cycle prefetching data from memory and transmitting a set number of bits on each signal line. The start of a data burst may be signaled by a rising edge, a trigger or an end of latency signal after a period of latency on a clock signal of the integrated circuit.

Various signal protocols may be used to implement memory data bursts. In one configuration used in the following examples each strobe signal may be associated with 8 data lines and strobe signal midpoints or edges are used to reference other features, attributes or events in the data signal. Regardless of the specific configuration laid out in the example, a method for sample point analysis will be described that can be used on any compatible set of signals.

In a first mode of operation, a first set of characteristic data is collected using an initial threshold voltage set for each signal line. Features in each bit of the digitized characteristic data may be located and identified in relation to features and events in the clock signal and the strobe signal. When read burst data and write burst data are used as characteristic data they may be bitwise processed in slightly different ways.

For read data, the end of the latency trigger or a first rising edge in the clock signal is located. Subsequently, strobe signal edges and midpoints between signal edges may be located in relation to edges in the clock signal. The approximate center of the data eye in the data signal may correspond to the strobe midpoint. From the data eye center the leading and trailing edges of the data eye may be located. A width of the bit or data eye is calculated as the difference between the leading and trailing edge time references. The logical state and width for the bit may be stored in memory.

For write data, the end of the latency trigger or a first rising edge in the clock is located. Subsequently, each strobe edge is located. The center or midpoint of the data eye of the data signal may correspond to the strobe edge position. From the data eye center the leading and trailing edges of the data eye are located. A width of the bit or data eye is calculated as the difference between the leading and trailing edge time references. The logical state and width for the bit may be stored in memory.

In the case of the read data burst only the rising edges of the latency clock may be used as references and for each rising edge two following strobe midpoints may be located. Alternatively, each rising and falling edge of the latency clock may be used to locate one corresponding strobe midpoint.

Similarly, in the case of the write data burst only the rising edges of the latency clock signal may be used as references and for each rising edge two strobe edges may be located. Alternatively, each rising and falling edge of the clock signal may be used to locate one corresponding strobe edge.

In both read and write bursts a subset of all the bits in the data burst may be used in determining a duty cycle.

In a second mode of operation, once the analyzer has analyzed each bit for each data line, a duty cycle for each signal line may be determined. An average high width may be determined as the sum of the high value widths divided by the number of high value widths for each signal line. The average low width may be determined as the sum of the low value widths divided by the number of low value widths for each signal line. The estimated duty cycle may then be the average high width divided by the sum of the average high width and the average low width.

The threshold voltage for each line is then reset to a value such that the resulting duty cycle for that signal line will approach the optimum duty cycle. The analyzer then captures and digitizes another set of characteristic data generated by the integrated circuit. The process of capturing, digitizing, identifying sample points, determining duty cycle and adjusting threshold voltage may be repeated or iterated until each data line operates within it's duty cycle tolerance.

A data analyzing system may be described in the following examples comprising a converter for generating a set of digitized signals including a first digitizing circuit connected to a first signal line with a first analog signal to create a first digitized timing signal, a second digitizing circuit connected to a second signal line with a second analog signal to create a second digitized timing signal and a third digitizing circuit with a first power supply providing a first threshold voltage connected to a third analog signal line to create a first digitized data signal. The system may further include memory storing software commands and a processor operably connected to the memory and the converter. The processor may execute the software commands in the memory to generate the set of digitized signals, identify a first triggering event in the first digitized timing signal, identify an element set of at least one element in the second digitized timing signal occurring subsequent to the first triggering event and define a plurality of signal features of the first digitized data signal. At least one of the plurality of signal features may be substantially simultaneous with at least one element of the element set. The processor may also determine a first duty cycle from the plurality of signal features of the first digitized data signal and set the first threshold voltage as a function of the first duty cycle.

In another example an analyzer system with threshold setting for analyzing a data burst may comprise a memory device with program instructions and data structures, a first digitizer connected to a clock signal line with a clock signal, a second digitizer connected to a strobe signal line with a strobe signal, a third digitizer connected to a first data signal line with a first data signal, a first threshold power supply connected to the third digitizer and a processor operably connected to the first digitizer, the second digitizer, the third digitizer, the first threshold power supply and the memory device.

In a first mode of operation the processor may be configured to determine time references of signal features including a trigger in the clock signal preceding the data burst, a strobe signal attribute, sequential leading edges and trailing edges in the first data signal and a midpoint in the first data signal located between the leading edge and the trailing edge and substantially simultaneous with the strobe signal attribute. In a second mode of operation the processor may be configured to calculate a first duty cycle for the first data signal based on the time references of the leading edge and the trailing edge and set a threshold voltage for the first threshold power supply based on the first duty cycle.

As used in the following discussion, signals may include features, attributes and events which may encompass rising edges, falling edges, midpoints between sequential edges and triggers such as a rising edge after a period of signal latency. Edges may be defined as a substantial change in voltage in a short period. Signals described in examples may be a portion of a data burst.

### DESCRIPTION OF DRAWINGS

FIG. 1 shows an analog waveform and a digital waveform with a 50% duty cycle.

FIG. 2 shows an analog waveform and a digital waveform with a duty cycle greater than 50%.

FIG. 3 shows an analog waveform and a digital waveform with a duty cycle less than 50%.

FIG. 4 is a block diagram of a signal analyzer system.

FIG. 5 is a static display of digitized waveforms for characteristic data such as read burst data.

FIG. 5A is a flow chart for sample point analysis and threshold setting for characteristic data such as read burst data.

FIG. 5B is a static display of digitized waveforms for characteristic data similar to those in FIG. 5 showing an alternate method for locating data signal features.

FIG. 6 is a static display of digitized waveforms for characteristic data such as write burst data.

FIG. 6A is a flow chart for sample point analysis and threshold setting for characteristic data such as write burst data.

FIG. 6B is a static display of digitized waveforms for characteristic data similar to those in FIG. 6 showing an alternate method for locating data signal features.

FIG. 7 is a flow chart of steps in sample point analysis.

FIG. 8 shows several digitized waveforms for data and strobe signals.

### DESCRIPTION

The following description and examples may use DDR3 memory as a specific example of an integrated circuit and a logic analyzer as a host for the analysis system. This example is for the purpose of description and illustration. The methods and processes described are applicable to any system that digitizes a plurality of analog signals and should not be limited by descriptions of specific hardware used in the examples. In the following figures and examples where similar features appear, similar numbering may be used from one figure to following figures.

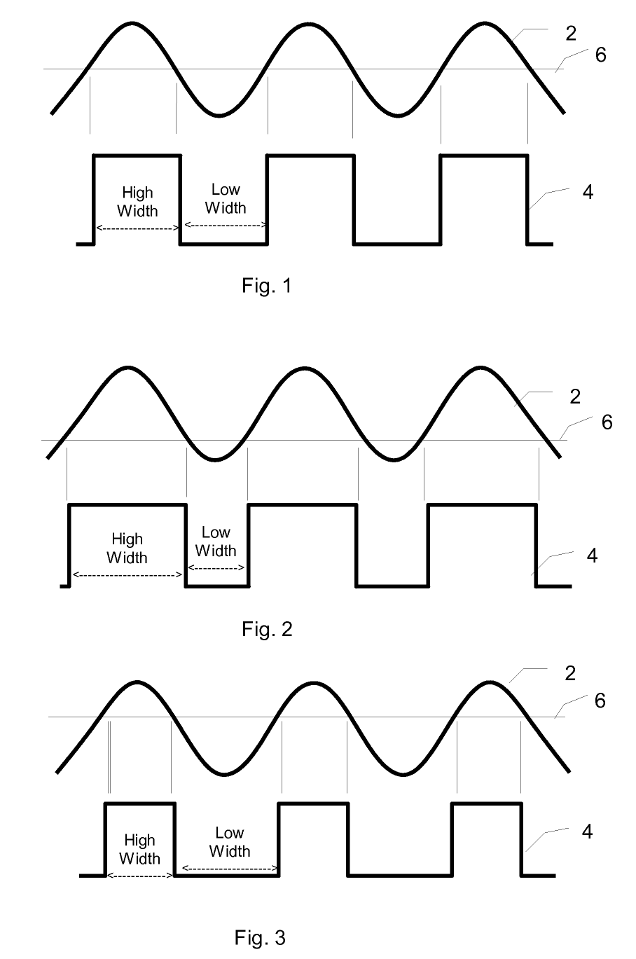

FIG. 1 shows an example of signal processing and includes an analog signal 2, a digitized signal 4 and a threshold 6. Analog signal 2 may be a signal generated by an integrated circuit such as a memory integrated circuit or other source. Threshold 6 may be a voltage reference generated by a power supply for digitizing analog signal 2. In digitizing analog signal 2 at sequential points in time the value of analog signal 2 may be compared to the value of threshold 6. The comparison may produce a true or false result at each point and the results may be displayed as digital signal 4. In this description, as is standard in the art, high and low, one and zero and on and off are essentially equivalent descriptions for this system.

A duty cycle may be defined for a digital signal as the ratio of the widths of the high cycle to the low cycle. In FIG. 1 the width of high cycles are equal to the width of low cycles so the duty cycle is equal to 50%.

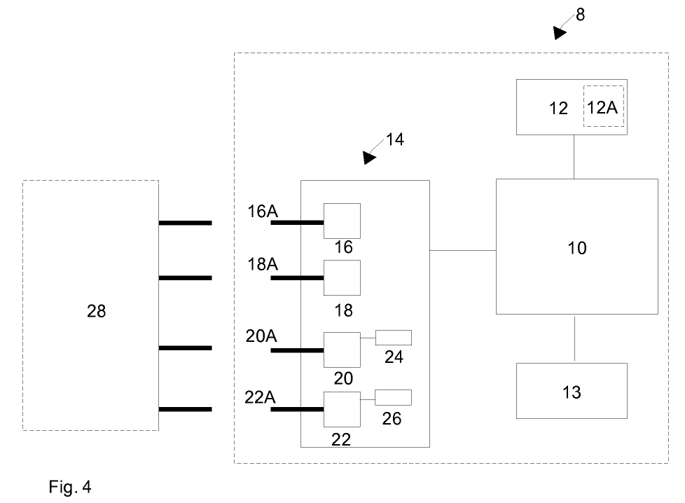

FIG. 2 shows signal processing similar to FIG. 1, but with a lower threshold setting. FIG. 2 again includes analog signal 2, digitized signal 4 and threshold 6. The comparison of analog signal 2 to threshold 6 again results in digitized signal 4. The widths of the high cycles here are greater than the widths of the low cycles. The determined duty cycle is greater than 50%.

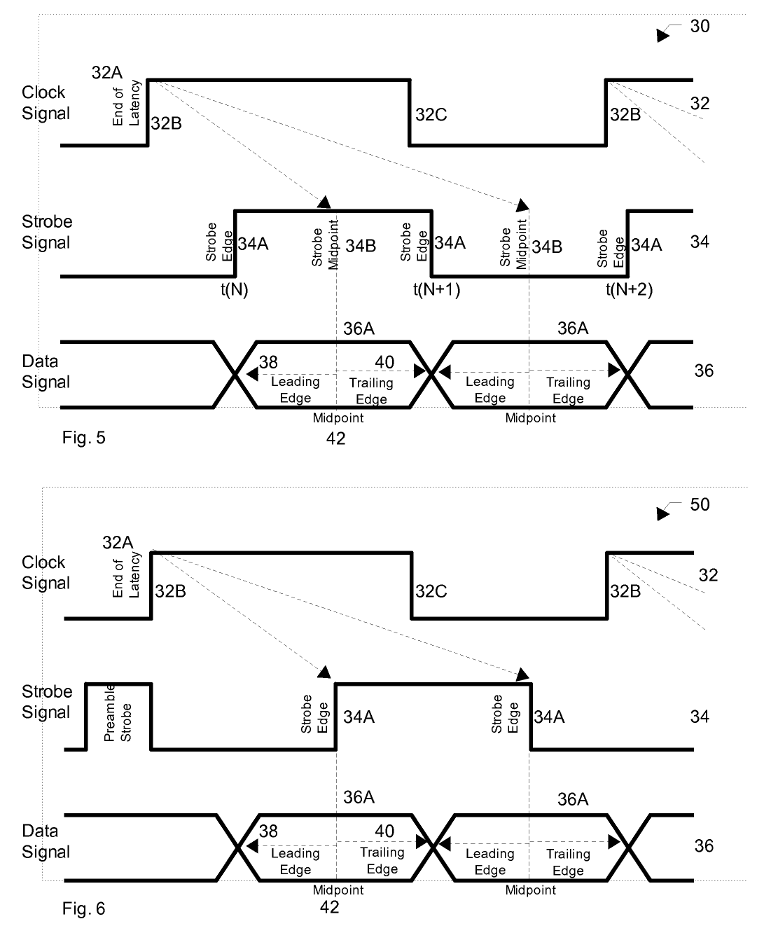

FIG. 3 again shows signal processing similar to FIG. 1 but with a higher threshold setting. FIG. 3 again includes analog signal 2, digitized signal 4 and threshold 6 and the comparison of analog signal 2 to threshold 6 results in digitized signal 4. The width of the high cycles here are much smaller than the widths of the low cycles. The determined duty cycle is less than 50%.

An estimated duty cycle may be determined from the average high width and average low width. An average high width may be determined as the sum of the high value widths divided by the number of high value widths for each signal line. The average low width may be determined as the sum of the low value widths divided by the number of low value widths for each signal line. The estimated duty cycle may then be the average high width divided by the sum of the average high width and the average low width:

$$Average High Width = \frac{\sum High Value Widths}{Number of High Value Widths}$$

$$Average Low Width = \frac{\sum Low Value Widths}{Number of Low Value Widths}$$

$$Estimated Duty Cycle = \frac{Average High Width}{\begin{matrix}Average High Width + \\ Average Low Width\end{matrix}}$$

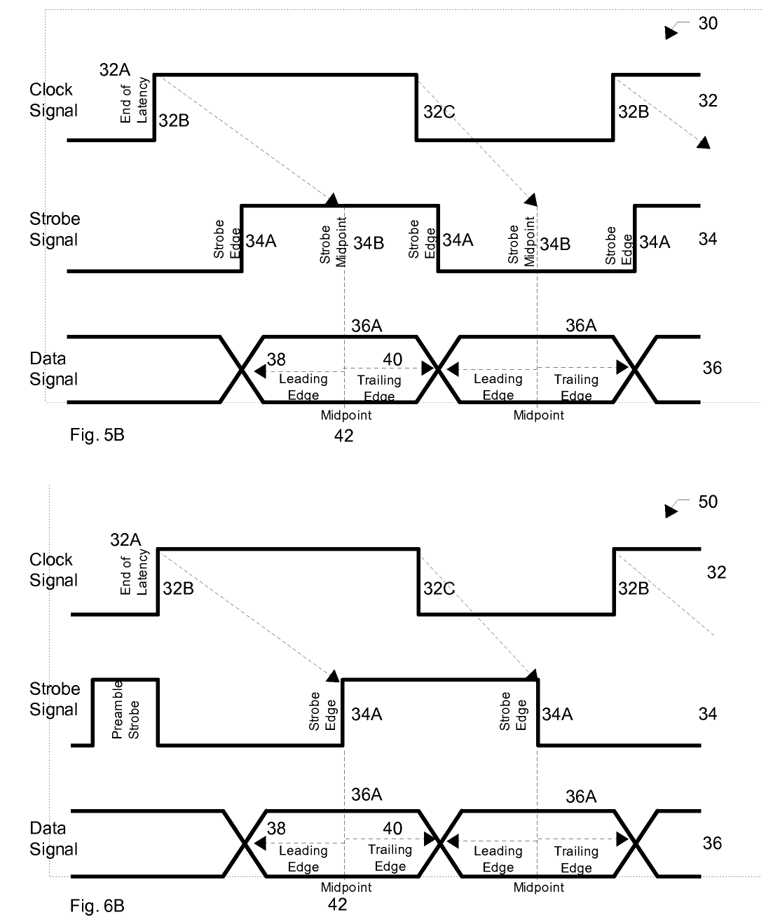

FIG. 4 shows a block diagram of a signal analysis system 8 including a processor 10, a memory or memory device 12 with data structure 12A, display 13 and digitizer or converter 14. Converter 14 may include a first digitizer 16 attached to an analog signal line 16A, a second digitizer 18 attached to analog signal line 18A, a third digitizer 20 attached to a third analog signal line 20A and a fourth digitizer 22 attached to a fourth analog signal line 22A. Converter 14 may further include a first power supply 24 attached to third digitizer 20 and a second power supply 26 attached to fourth digitizer 22. Power supplies 24 and 26 may be operatively connected to and controlled by processor 10 to generate variable voltages as thresholds for digitizing analog signals. Signal analysis system 8 is shown in association with signal source 28. Signal source 28 could be any one or more lines carrying analog signals such as an integrated circuit (IC) or a data bus.

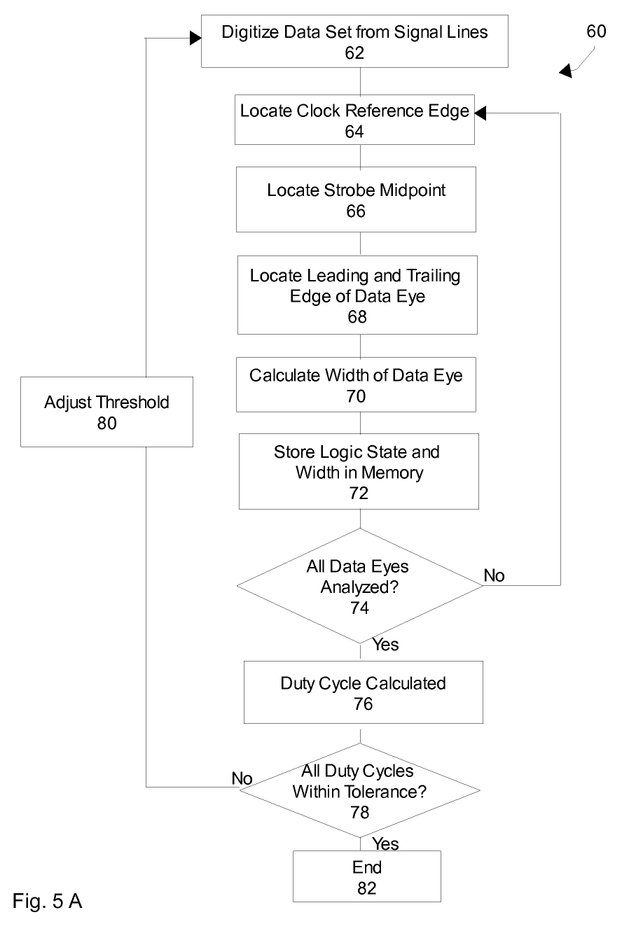

FIG. 5 shows a set of digitized signals 30 associated with analysis of signals from a signal source 28 as they may be generated by converter 14 and displayed by signal analyzer or signal analysis system 8. The horizontal axis may represent time in these signals and the vertical axis may represent a voltage or high/low reference. Each point shown may be described by a voltage and a time reference. Signals 30 include a clock signal 32 with an end of latency 32A, rising signal edge or edges 32B and falling signal edge or edges 32C, a strobe signal 34 with strobe signal edge or edges 34A and strobe signal midpoint or midpoints 34B, and a data signal 36 with a series of data bits or data eye or eyes 36A. Data eyes 36A include leading edge or edges 38, trailing edge or edges 40 and data centers, midpoint or midpoints 42.

Digitized signals 30 may represent a portion of a read data burst from a DDR3 memory circuit. Data eyes 36A may be equivalent to data bits or each data eye may be a set of data bit values superimposed. Clock signal 32 and strobe signal 34 may comprise timing signals.

To determine the duty cycle of digitized signal 36 the location or time reference of several specific signal events, attributes or features may be determined including leading edge 38 and trailing edge 40 of bit or data eye 36A. Here each strobe midpoint 34B in strobe signal 34 is located in reference to each rising edge 32B of clock signal 32. Strobe midpoints 34B may be located by determining time references for two sequential strobe edges 34A of strobe signal 34 immediately following rising edge 32B of clock signal 32. The time reference for midpoint 34B may be the average value of the time references for the two sequential strobe edges 34A. The time reference for midpoint 34B may then be applied to data signal 36 to define midpoint 42 of data eye 36A.

FIG. 5A is a flow chart describing steps in a method of sample point analysis and threshold setting 60 of signals 30 of FIG. 5. In step 62 a signal on each signal line is read and digitized simultaneously or synchronously. In step 64 a reference edge in clock signal 32 is determined such as end of latency 32A, rising edge 32B or falling edge 32C. In step 66 the location of strobe midpoint 34B is located which for read data may correspond to approximate data eye center or midpoint 42. In step 68 the location of leading edge 38 and trailing edge 40 of data eye 36A are determined. In step 70 the width of data eye 36A is calculated as the location of trailing edge 40 minus the location of leading edge 38. In step 72 the logical state and the width are stored in memory 12. At step 74 if each selected data eye 36A from each signal line has been analyzed, the duty cycle is calculated in step 76, else control returns to step 64. At step 78 if all duty cycles are within tolerance, method 60 ends at step 82. If all the duty cycles are not within tolerance, threshold 6 is adjusted for each data signal 36 in step 80 and control returns to step 62 to collect another set of data.

FIG. 5B is a static display of digitized waveforms similar to FIG. 5 including clock signal 32 with an end of latency 32A, strobe signal 34 with strobe edge or edges 34A and strobe midpoint or midpoints 34B and characteristic data signal 36 with data eye or eyes 36A. Here in an alternate method each strobe midpoint 34B in strobe signal 34 is located in reference to one edge 32B or 32C of clock signal 32. Strobe midpoint 34B may again be located by determining time references for two sequential strobe edges 34A of strobe signal 34 and taking the average of the two time references.

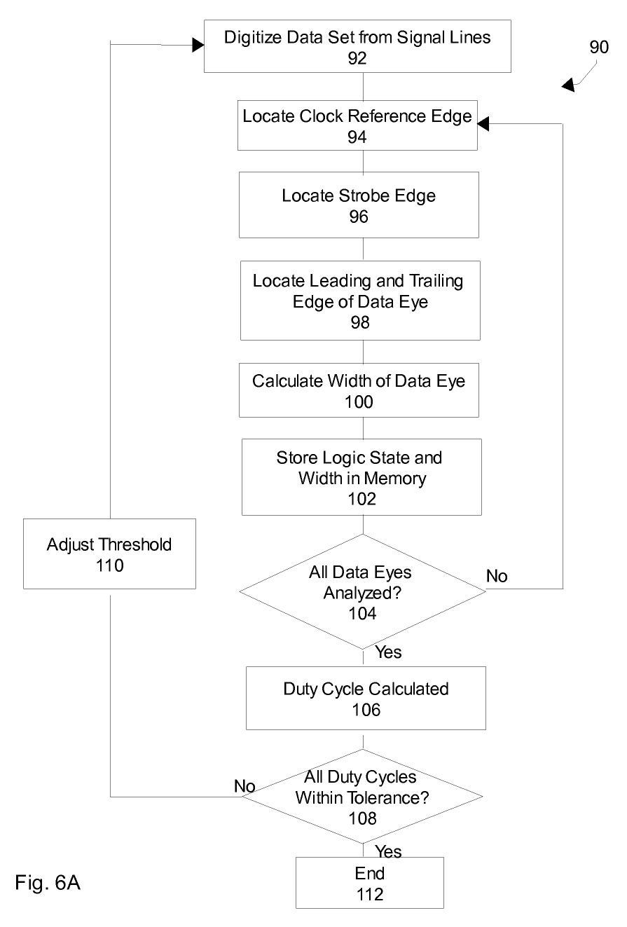

FIG. 6 shows another set of digitized signals 50 similar to those in FIG. 5 associated with analysis of analog signals generated by signal source 28 as they may be displayed on an analyzer. Again, the horizontal axis may represent time and the vertical axis may represent a voltage or high/low reference. Signals 50 include a clock signal 32 with an end of latency 32A, rising edge or edges 32B and falling edge or edges 32C, a strobe signal 34 with strobe edge or edges 34A and a data signal 36 with a data eye or data eyes 36A. Data eyes 36A include a leading edge 38, a trailing edge 40 and a data center, midpoints or midpoint 42. To determine the duty cycle of digitized signal 36, the location or time reference of several specific signal events, attributes or features may be determined including leading edge 38 and trailing edge 40 of data eye 36A.

Digitized signals 50 may represent a portion of a write data burst from a DDR3 memory circuit. A selected subset of data burst data bits may again be used in calculating the duty cycle. Clock signal 32 and strobe signal 34 may again comprise timing signals.

FIG. 6A is a flow chart describing steps in a method of sample point analysis and threshold setting 90 of signals 50 of FIG. 6. In step 92 data on each signal channel is collected and digitized simultaneously or synchronously. In step 94 a clock signal reference edge such as rising edge 32B may be located. In step 96 the location of strobe edge 34A is located which for write data may correspond to approximate data eye center or midpoint 42. In step 98 the location of leading edge 38 and trailing edge 40 of data eye 36A are determined. In step 100 the width of data eye 36A is calculated as the location of trailing edge 40 minus the location of leading edge 38. In step 102 the logical state and the width are stored in memory 12. At step 104 if each selected data eye 36A from each signal line has been analyzed, the duty cycle is calculated in step 106, else control returns to step 94 to analyze the next data eye 36A. At step 108 if all duty cycles are within tolerance, method 90 ends at step 112. If all the duty cycles are not within tolerance, threshold 6 is adjusted for each data signal 36 in step 110 and control returns to step 92 to collect another set of data.

FIG. 6B is a static display of digitized waveforms 50 similar to FIG. 6 including clock signal 32 with a rising edge 32B and falling edge 32C, strobe signal 34 with strobe edges 34A and characteristic data signal 36 with data eyes 36A. Here, in an alternative method, one strobe edge 34A in strobe signal 34 is located in reference to one edge 32B or 32C of clock signal 32. The time reference of each strobe edge 34A may then be applied to data signal 36 to define a midpoint 42 for a data eye 36A.

While these examples show examples of timing signals and data signals, signal source 28 may include different combinations of timing signals and data signals. Signal source 28 may comprise multiple strobe signals 34 with each strobe signal 34 corresponding to multiple data signals 36. For example, signal source 28 may comprise eight strobe signals 34 with each strobe signal 34 corresponding to eight data signals 36. In another example signal source 28 may include error correction signals similar to data signal 36 with corresponding strobe signals 34 and/or clock signals 32. Any number or combination of signals as described used in a similar function as described will fall within the scope of this disclosure.

Returning to FIG. 5 strobe signal 34 may include strobe edges 34A. Each strobe edge 34A may have a time reference such as t(N), t(N+1) and t(N+2) as noted. Each strobe midpoint 34B may be determined by the formula:

t(Midpoint)=t(N)+(t(N+1)−t(N))/2.

The last bit or other bits of the data burst selected to calculate duty cycle may not have a strobe edge for calculating a strobe midpoint necessary for locating the corresponding midpoint 42 in data signal 36. In this case the midpoint of strobe signal 34 may be determined by the formula:

t(Midpoint)=t(N)+(t(N)−t(N−1))/2

or a similar formula.

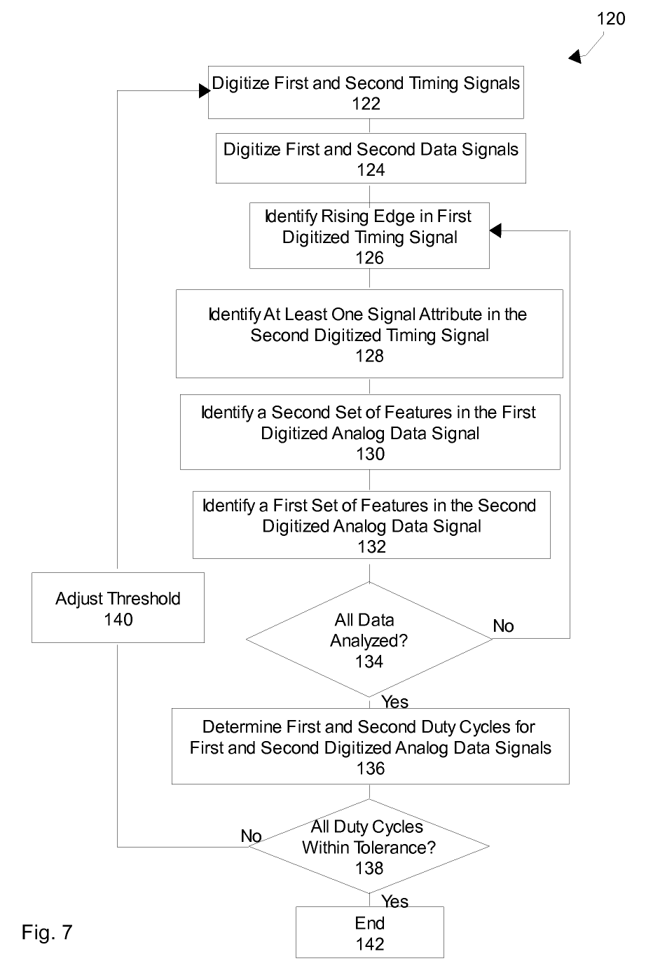

FIG. 7 is a flow chart describing steps for a method 120 for analyzing a plurality of data signals. Method 120 may include step 122 creating a first digital timing signal by digitizing a first analog timing signal and creating a second digital timing signal by digitizing a second analog timing signal. Step 124 creates a first digital data signal by digitizing a first analog data signal at a first threshold voltage and creating a second digital data signal by digitizing a second analog data signal at a second threshold voltage. Step 126 identifies an edge in the first digitized timing signal such as end of latency signal 32A or rising edge 32B or other signal edge. Step 128 identifies an attribute group of at least one signal attribute in the second digitized timing signal subsequent to the rising edge identified in step 126.

Step 130 identifies a first set of features such as a leading edge 38, trailing edge 40 and/or a data center 42 in the first digital data signal where data center 42 is substantially simultaneous with at least one attribute in the attribute group. In step 132 a second set of features is identified which may include leading edge 38, a trailing edge 40 and/or data center 42 in the second digital data signal where data center 42 is substantially simultaneous with at least one attribute in the attribute group. At step 134 if all the selected data bits from each signal line have been analyzed, then step 136 determines a first and second duty cycle for the first and second digital data signals. If all the selected data bits have not been analyzed, control returns to step 126. At step 138 if all duty cycles are within tolerance, method 120 ends at step 142. If all the duty cycles are not within tolerance, threshold 6 is adjusted for each channel in step 140 and control returns to step 122 to collect another set of data.

The flow of steps in methods such as at 134 and 138 which returns control to a previously completed step and repeats some or all of the steps may constitute iterative operation. Iterative operation of this system where steps are repeated may be configured to optimize a variable such as duty cycle.

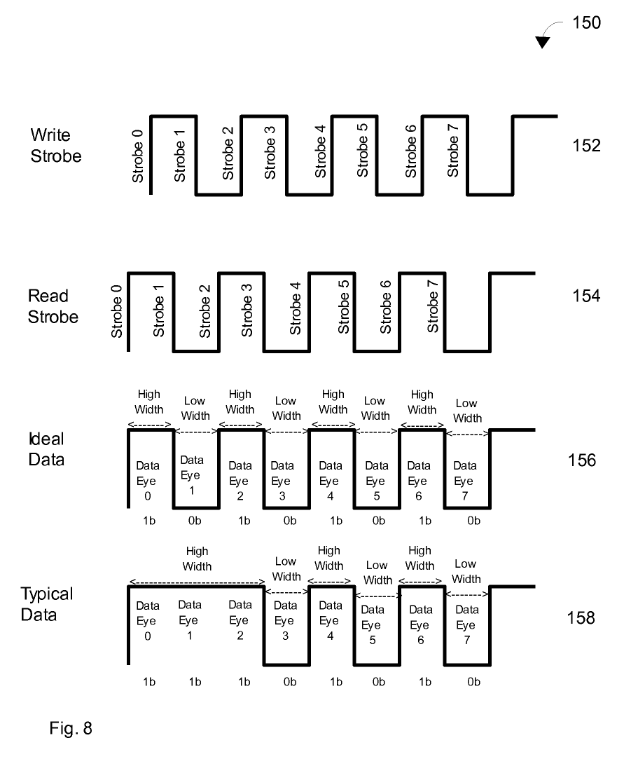

FIG. 8 shows analog signals 150 that may be generated by signal source 28 which are digitized and graphically displayed by analyzer system 8. Signals 150 may include a write strobe 152, a read strobe 154, ideal data 156 and typical data 158. Ideal data 156 displays sequential alternating 0 and 1 bits or low and high bits as generated by signal source 28.

Typical data 158 includes series of bits that do not alternate between 0s and 1s. This may result in bits with no leading and/or trailing edge as illustrated by data eye 1. In this case only the selected subset of data eyes 3, 4, 5, 6 and 7 may be used in determining duty cycle.

In this example an acceptable duty cycle value may be defined as 50%±3%. Any duty cycle that falls within this range may result in no adjustment to the threshold value for that signal line. A duty cycle falling instead within another duty cycle range may result in a threshold adjustment. In a typical process there may be a standard or base threshold adjustment such as 1% of the signal range. Memory 12 may include data structure 12A with duty cycle references and corresponding voltage factors. Duty cycle references may be a range of values or a maximum and a minimum value for the duty cycle range. The voltage factors may be an actual voltage value, a multiplier or an adjustment value. Table 1 shows a typical data structure 12A including a set of duty cycle ranges or references and corresponding voltage factors.

TABLE 1

| Duty Cycle | Voltage |
|---|---|
| Range | Factors |
| 47-53 | 0x |
| 45-47 | −1x |
| 40-45 | −2x |
| 0-40 | −4x |
| 53-55 | 1x |
| 55-60 | 2x |
| 60-100 | 4x |

A duty cycle falling within the range of 45%-47% may correspond to a threshold adjustment of minus one times the standard adjustment. A duty cycle falling within the range of 53%-55% may result in a threshold adjustment of plus one times the standard adjustment value.

The adjustments to threshold 6 may be scaled or logarithmic in relation to the duty cycle offset. A duty cycle falling within the range of 0%-40% may result in a threshold adjustment of minus four times the standard adjustment and a duty cycle falling within the range of 60%-100% may result in a threshold adjustment of plus four times the standard adjustment value.

As an example, assume the threshold voltage range is 0-10 volts, the standard adjustment of 1% is 0.1 volts and the threshold voltage is set at 4 volts. Four times the standard adjustment will be 0.4 volts and the threshold voltage will be reset to 4.4 volts. When each data line is evaluated and each threshold value set, a new set of attribute data may be collected and analyzed.

Alternatively, data structure 12A may be implemented as an equation or algorithm stored in memory 12. The algorithm when executed by processor 10 may generate a voltage value as the threshold 6 based on the determined duty cycle. The voltage change generated may be a logarithmic change in relation to the duty cycle offset from the optimum duty cycle value.

While embodiments of an electronic signal digitizing system and methods of use have been particularly shown and described, many variations may be made therein. The described system and methods are examples and are not to be used as limitations. Any suitable configuration or combination of components or process steps presented, or equivalents to them that perform a similar function, may also be used and fall within the scope of this disclosure.

This disclosure may include one or more independent or interdependent inventions directed to various combinations of features, functions, elements and/or properties, one or more of which may be defined in the following claims. Other combinations and sub-combinations of features, functions, elements and/or properties may be claimed later in this or a related application. Such variations, whether they are directed to different combinations or directed to the same combinations, whether different, broader, narrower or equal in scope, are also regarded as included within the subject matter of the present disclosure. An appreciation of the availability or significance of claims not presently claimed may not be presently realized. Accordingly, the foregoing embodiments are illustrative, and no single feature or element, or combination thereof, is essential to all possible combinations that may be claimed in this or a later application. Each claim defines an invention disclosed in the foregoing disclosure, but any one claim does not necessarily encompass all features or combinations that may be claimed. Where the claims recite “a” or “a first” element or the equivalent thereof, such claims include one or more such elements, neither requiring nor excluding two or more such elements. Further, ordinal indicators, such as first, second or third, for identified elements are used to distinguish between the elements, and do not indicate a required or limited number of such elements, and do not indicate a particular position or order of such elements unless otherwise specifically stated.

We claim:

1. A data analyzing system comprising:
a converter for generating a set of digitized signals including:
a first digitizing circuit connected to a first signal line with a first analog signal to create a first digitized timing signal;
a second digitizing circuit connected to a second signal line with a second analog signal to create a second digitized timing signal;
a third digitizing circuit with a first power supply providing a first threshold voltage connected to a third analog signal line to create a first digitized data signal;
memory with software commands; and
a processor operably connected to the memory and the converter where the processor executes the software commands in the memory to:
generate the set of digitized signals;
identify a first triggering event in the first digitized timing signal;
identify an element set of at least one element in the second digitized timing signal occurring subsequent to the first triggering event;
define a plurality of signal features of the first digitized data signal where at least one of the plurality of signal features is substantially simultaneous with at least one element of the element set;
determine a first duty cycle from the plurality of signal features of the first digitized data signal; and
set the first threshold voltage as a function of the first duty cycle.

2. The data analyzing system of claim 1 where the converter further includes a fourth digitizing circuit with a second power supply providing a second threshold voltage connected to a fourth analog signal line to create a second digitized data signal and the processor executes the software commands in the memory to:
define a plurality of signal features of the second digitized data signal where at least one of the plurality of signal features is substantially simultaneous with at least one element of the element set;
determine a second duty cycle from the plurality of signal features of the second digitized data signal; and
set the second threshold voltage as a function of the second duty cycle.

3. The data analyzing system of claim 1 where at least a portion of the software commands in the memory are executed iteratively by the processor until the first duty cycle is within a defined range.

4. The data analyzing system of claim 1 where the first timing signal is a clock signal and the second timing signal is a strobe signal.

5. The data analyzing system of claim 1 where the defined plurality of signal features of the first digitized data signal includes a leading edge, a trailing edge and a midpoint where the midpoint is substantially simultaneous with at least one element of the element set.

6. The data analyzing system of claim 1 where the set of digitized signals includes a data burst of four or eight bits.

7. The data analyzing system of claim 1 where the memory further includes duty cycle values and corresponding voltage factors and the processor executes software commands in memory to generate a threshold voltage at the first power supply as a function of the duty cycle and the corresponding voltage factor.

8. A method for analyzing a plurality of data signals comprising:
creating a first digital timing signal by digitizing a first analog timing signal;
creating a second digital timing signal by digitizing a second analog timing signal;
creating a first digital data signal by digitizing a first analog data signal at a first threshold voltage;
creating a second digital data signal by digitizing a second analog data signal at a second threshold voltage;
identifying a rising edge in the first digital timing signal;
identifying an attribute group of at least one signal attribute in the second digital timing signal subsequent to the rising edge;
identifying a first set of features including a leading edge, a trailing edge and a data center in the first digital data signal where the data center is substantially simultaneous with at least one attribute from the attribute group;
identifying a second set of features including a leading edge, a trailing edge and a data center in the second digital data signal where the data center is substantially simultaneous with at least one attribute in the attribute group;
determining a first duty cycle for the first digital data signal; and
determining a second duty cycle for the second digital data signal.

9. The method for analyzing a plurality of data signals of claim 8 further comprising:
defining a data structure including a plurality of duty cycle references and corresponding voltage factors;
selecting a first voltage factor from the data structure based on the first duty cycle;
setting the first threshold voltage based on the first selected voltage factor;
selecting a second voltage factor from the data structure based on the second duty cycle; and
setting the second threshold voltage based on the second selected voltage factor.

10. The method for analyzing a plurality of data signals of claim 8 where the method at least in part is iteratively executed to optimize the first duty cycle and the second duty cycle.

11. The method for analyzing a plurality of data signals of claim 8 where the first digital timing signal is a clock signal and the second digital timing signal is a strobe signal.

12. The method for analyzing a plurality of data signals of claim 8 where the plurality of data signals includes a read burst and the second digital timing signal is a strobe signal and at least one attribute in the attribute group is a midpoint between two sequential strobe edges.

13. The method for analyzing a plurality of data signals of claim 8 where the plurality of data signals includes a write burst and the second digital timing signal is a strobe signal and at least one attribute in the attribute group is a strobe edge.

14. An analyzer system with threshold setting for analyzing a data burst comprising:
a memory device with program instructions and a data structure;
a first digitizer connected to a clock signal line with a clock signal;
a second digitizer connected to a strobe signal line with a strobe signal;
a third digitizer connected to a first data signal line with a first data signal;
a first threshold power supply connected to the third digitizer; and
a processor operably connected to the first digitizer, the second digitizer, the third digitizer, the first threshold power supply and the memory device;
where in a first mode the processor is configured to determine time references of signal features including:
a trigger in the clock signal preceding the data burst;
an attribute in the strobe signal;
a leading edge and a trailing edge in the first data signal; and
a midpoint in the first data signal located between the leading edge and the trailing edge and substantially simultaneous with the strobe signal attribute;
where in a second mode the processor is configured to:
calculate a first duty cycle for the first data signal based on the time references of the leading edge and the trailing edge; and
set a threshold voltage for the first threshold power supply based on the first duty cycle.

15. The analyzer system of claim 14 where the data structure includes duty cycle references and voltage factors and in the second mode setting the threshold voltage for the first threshold power supply includes determining a voltage factor from the data structure based on the first duty cycle.

16. The analyzer system of claim 14 where the first mode operates at least in part iteratively to process the data burst.

17. The analyzer system of claim 14 where the strobe signal attribute is an edge.

18. The analyzer system of claim 14 where the strobe signal attribute is a midpoint.

19. The analyzer system of claim 14 where the analyzer system operates at least in part iteratively to optimize the first duty cycle.

20. The analyzer system of claim 14 further comprising:
a fourth digitizer connected to a second data signal line with a second data signal;
a second threshold power supply connected to the fourth digitizer;
where in the first mode the processor is further configured to identify time references for signal features including:
a leading edge and a trailing edge in the second data signal; and
a midpoint in the second data signal located between the leading edge and the trailing edge and substantially simultaneous with the strobe signal attribute;
where in the second mode the processor is configured to:
calculate a second duty cycle for the second data signal based on the time references for the leading edge and the trailing edge; and
set a threshold voltage for the second threshold power supply based on the second duty cycle.
